(19) United States
(12) Patent Application Publication
(10) Pub. No.: US 2026/0222744 A1
(43) Pub. Date: Jul. 30, 2026

(54) PIEZOELECTRIC MICROELECTROMECHANICAL DEVICE WITH CONVERGING AND DIVERGING AIRFLOW REGIONS

(71) Applicant: QUALCOMM Incorporated, San Diego, CA (US)

(72) Inventors: Christian OBERMAIER, München (DE); Hamid BASAERI, Medford, MA (US); Matthias JUNGKUNZ, Munich (DE); Robert John LITTRELL, Belmont, MA (US); Michael MERKER, München (DE)

(21) Appl. No.: 19/287,744

(22) Filed: Jul. 31, 2025

Related U.S. Application Data
(60) Provisional application No. 63/750,709, filed on Jan. 28, 2025.

(51) Int. Cl. H04R 17/02; H04R 31/00; H10N 30/50; H10N 30/88

(52) U.S. Cl. CPC H04R 17/02; H04R 31/00; H10N 30/50; H10N 30/88; H04R 2201/003

(57) ABSTRACT

Aspects of the disclosure relate to piezoelectric microelectromechanical systems (MEMS) devices. A piezoelectric MEMS device may include a transducer body including an acoustic cavity extending from a bottom surface to a top surface; and a substrate including a plurality of layers and coupled to the bottom surface of the transducer body, the substrate including a hole formed by the plurality of layers, and wherein the plurality of layers comprises a solder mask, a top metal layer, and a plurality of tapered layers below the top metal layer having incrementally varying aperture sizes relative to at least one adjacent layer.

### CROSS-REFERENCE TO RELATED APPLICATIONS

This application claims the benefit of U.S. Provisional Ser. No. 63/750,709, filed Jan. 28, 2025, which is hereby incorporated by reference in its entirety and for all purposes.

### TECHNICAL FIELD

This disclosure relates generally to acoustic transducers. For example, aspects of this disclosure relate to piezoelectric microelectromechanical systems (MEMS) devices with converging and diverging regions.

### BACKGROUND

Microelectromechanical system (MEMS) devices can be used in a variety of contexts. Piezoelectric MEMS devices, for example, can be used as transducers. A MEMS acoustic transducer/sensor converts acoustic energy into electrical signal, and/or converts an electrical signal into acoustic energy. An example of a MEMS acoustic transducer is a MEMS microphone, which converts sound pressure into an electrical voltage. Based on their transduction mechanisms, MEMS microphones can be made in various forms, such as capacitive microphones or piezoelectric microphones.

MEMS capacitive microphones and electric condenser microphones (ECMs) currently dominate the consumer electronics market for microphones. Piezoelectric MEMS microphones, however, occupy a growing portion of the consumer market, and have unique advantages compared to their capacitive counterparts. Among other things, piezoelectric MEMS microphones do not require a back plate, eliminating the squeeze film damping, which is an intrinsic noise source for capacitive MEMS microphones. In addition, piezoelectric MEMS microphones are reflow-compatible and can be mounted to a printed circuit board (PCB) using typical lead-free solder processing, which could irreparably damage typical ECMs.

### SUMMARY

Aspects of the present disclosure describe devices, systems, and methods for fabrication of piezoelectric microelectromechanical system (MEMS) devices. According to at least one illustrative example, a MEMS transducer is provided. The MEMS transducer includes a transducer body including an acoustic cavity extending from a bottom surface to a top surface; and a substrate including a plurality of layers and coupled to the bottom surface of the transducer body, the substrate including a hole formed by the plurality of layers, wherein the plurality of layers comprises a solder mask, a top metal layer, and a plurality of tapered layers below the top metal layer having incrementally varying apertures relative to at least one adjacent layer.

In some aspects, one or more of the apparatuses described above is, is part of, or includes a mobile device (e.g., a mobile telephone or so-called “smart phone” or other mobile device), a wearable device, an extended reality device (e.g., a virtual reality (VR) device, an augmented reality (AR) device, or a mixed reality (MR) device), a personal computer, a laptop computer, a server computer, a vehicle (e.g., a computing device of a vehicle), or other device. In some aspects, an apparatus includes a camera or multiple cameras for capturing one or more images. In some aspects, the apparatus includes a display for displaying one or more images, notifications, and/or other displayable data. In some aspects, the apparatus can include one or more sensors. In some cases, the one or more sensors can be used for determining a location and/or pose of the apparatus, a state of the apparatuses, and/or for other purposes.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF DRAWINGS

FIG. 1 illustrates a microelectromechanical systems (MEMS) transducer in accordance with aspects described herein;

FIG. 2 is a perspective view of a piezoelectric cantilever and stress applied at different portions of the piezoelectric cantilever;

FIG. 3A illustrates aspects of a MEMS sensor in accordance with aspects described herein;

FIG. 3B illustrates a cross-section of a MEMS sensor in accordance with some aspects of the disclosure;

FIG. 4 illustrates aspects of a piezoelectric MEMS sensor in accordance with aspects described herein;

FIG. 5A illustrates a plan view of a MEMS piezoelectric transducer in accordance with some aspects of the disclosure;

FIG. 5B illustrates a cross-sectional view of a MEMS piezoelectric transducer in accordance with some aspects of the disclosure;

FIG. 5C illustrates a plan view of another MEMS piezoelectric transducer in accordance with some aspects of the disclosure;

FIG. 6A is a perspective view of a packaged MEMS transducer that includes a plurality of MEMS transducers encapsulated by a protective cover in accordance with some aspects of the disclosure;

FIG. 6B is an enlarged perspective view of a packaged MEMS transducer 600 that in accordance with some aspects of the disclosure;

FIG. 6C is a cross-sectional view of a MEMS sensor 630 in accordance with some aspects of the disclosure;

FIG. 6D is a cross-sectional view of a MEMS sensor 655 in accordance with some aspects of the disclosure;

FIG. 7 is a perspective view of a cross-section of a MEMS transducer 700 and illustrating a bottom surface in accordance with some aspects of the disclosure;

FIG. 8 illustrates a method for manufacturing piezoelectric devices in accordance with aspects described herein; and

FIG. 9 is a block diagram of a computing device that can include a MEMS device in accordance with aspects described herein.

Like reference symbols in the various drawings indicate like elements.

### DETAILED DESCRIPTION

The detailed description set forth below in connection with the appended drawings is intended as a description of example aspects and implementations and is not intended to represent the only implementations in which the invention may be practiced. The detailed description includes specific details for the purpose of providing a thorough understanding of the example aspects and implementations. In some instances, some devices are shown in block diagram form. Drawing elements that are common among the following figures may be identified using the same reference numerals.

Piezoelectric devices operate using the piezoelectric effect, where mechanical displacement in a piezoelectric material generates an electrical charge. The electrical charge can be converted into a voltage by adding electrodes. Piezoelectric devices can operate as transducers for converting electrical energy into sound waves or mechanical energy from acoustic waves into electrical energy.

Piezoelectric devices are manufactured using semiconductor processes and result in remarkably small products. Their compact size allows piezoelectric devices to be embedded in tiny sensors, wearable devices, and even medical implants without significantly impacting the design or weight of these devices and are used in devices that require energy harvesting or precise actuation in limited spaces.

In some aspects, microelectromechanical systems (MEMS) transducers may be tested for reliability based on extreme conditions. For example, a reliability test of a MEMS transducer can include a pressure test that applies a large volume of pressure into the MEMS transducer in a short time. For example, an air gun may inject a large volume of air pressure into MEMS transducers to evaluate the lifecycle of the MEMS transducer, which may damage or even destroy piezoelectric materials of the MEMS transducer that generate electrical signals. The MEMS transducers can be designed to satisfy this test and otherwise be able to withstand high air pressure events by increasing the rigidity of piezoelectric materials.

Package geometry of MEMS transducers can play an important role in enhancing the survivability of microphones during these tests, balancing and redirecting the airflow, and modifying the impact on the piezoelectric materials. Package geometry can influence microphone performance by introducing varying levels of acoustic resistance and acoustic mass loading. For example, increased acoustic resistance results in higher noise levels, and greater mass loading leads to a drop in the resonance of the plates and reduced signal-to-noise ratio. Generally, package geometries that offer more openings provide better acoustic performance but reduce the microphone's ability to withstand high-pressure air.

Aspects described herein include MEMS acoustic transducers with piezoelectric cantilevers. A MEMS transducer includes a transducer body including an acoustic cavity extending from a bottom surface to a top surface and a substrate including a plurality of layers coupled to the bottom surface of the transducer body, the substrate including a hole and formed by the plurality of layers. The plurality of layers comprises a solder mask, a top metal layer, and a plurality of tapered layers below the top metal layer having different lengths extending toward the center of the hole incrementally varying apertures (e.g., apertures with varying aperture sizes) relative to at least one adjacent layer.

In some aspects, the hole comprises a converging inlet, a diverging outlet, and a middle region between the converging inlet and the diverging outlet including a converging region or a diverging region. The diverging outlet or converging inlet are configured to minimize acoustic mass loading and acoustic resistance and prevent physical damage to the transducer during reliability tests (e.g., enabling the transducer to survive extreme conditions of the reliability tests).

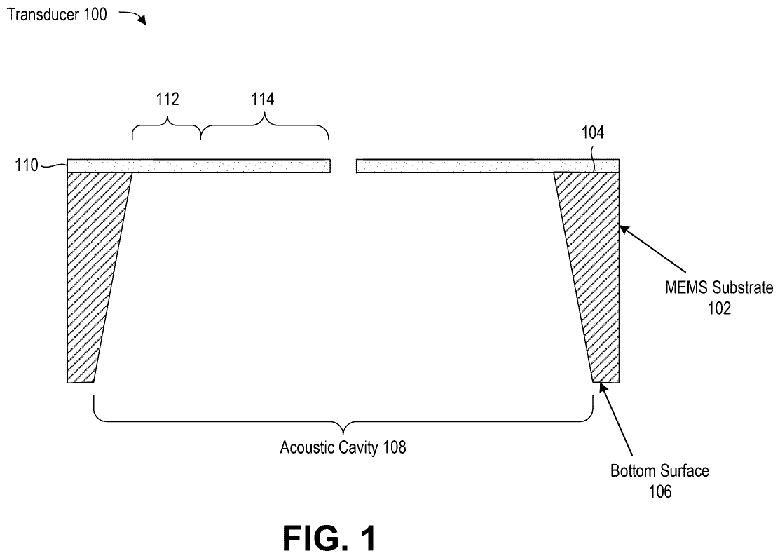

FIG. 1 illustrates a MEMS transducer 100 in accordance with aspects described herein. The MEMS transducer 100 includes a MEMS substrate 102 (e.g., a semiconductor substrate such as silicon (Si)) having a top surface 104 and a bottom surface 106. An acoustic cavity 108 is formed through the MEMS substrate 102, with the acoustic cavity 108 bounded by an aperture in the top surface 104 and an aperture in the bottom surface 106. An electroacoustic structure 110 is formed at or above the top surface 104 and an aperture of the top surface 104. The electroacoustic structure 110 includes an acoustic layer to receive acoustic vibrations passing through the acoustic cavity 108 and transduce the vibrations (e.g., sound) into an electrical signal via the electroacoustic structure 110.

In one aspect, the electroacoustic structure 110 includes a piezoelectric structure configured to convert mechanical energy into electrical energy. For example, the acoustic cavity 108 receives physical energy (e.g., acoustic signals) through the electroacoustic structure 110 and displaces (e.g., vibrates) based on the physical energy. The electroacoustic structure 110 may be a piezoelectric cantilever that includes a sensing region 112 and a lever region 114. The vibrations applied to the acoustic cavity 108 may be converted into electrical energy based on the piezoelectric effect that is applied to the lever region 114 and the sensing region 112. The piezoelectric effect is the ability of certain materials (e.g., quartz) to generate an electric charge in response to an applied mechanical stress. For example, a voltage can be generated based on providing an acoustic signal into the electroacoustic structure 110.

In some aspects, the energy produced by the electroacoustic structure 110 is based on the mechanical stress captured at an electrode. When a piezoelectric material (e.g., the electroacoustic structure 110) is compressed, the piezoelectric material generates a charge proportional to the applied force based on an electrode disposed within the area occupied by the electrode. The generated electrical charge and the capacitance of the electrode, which is based on the geometry of the electrode and dielectric properties, determine the generated voltage.

In some aspects, the electroacoustic structure 110 includes a plurality of piezoelectric cantilevers that are configured to cover the acoustic cavity 108. The piezoelectric cantilevers respond to acoustic pressure and each generates an electrical signal.

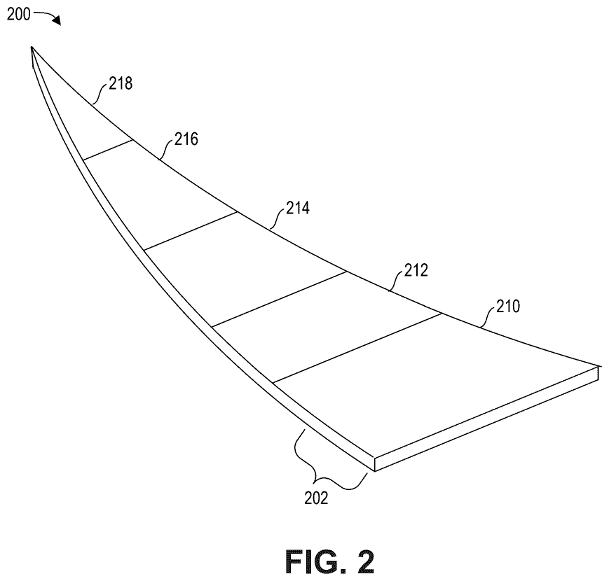

FIG. 2 is a perspective view of a piezoelectric cantilever and stress applied at different portions of the piezoelectric cantilever. The piezoelectric cantilever 200 is being displaced due to an acoustic signal (e.g., mechanical energy) and different stress is applied to the piezoelectric cantilever 200 based on distance from an anchor region 202. The anchor region 202 is mechanically attached to the top surface of a transducer (e.g., the top surface 104 in FIG. 1), and stress applied to the piezoelectric cantilever 200 increases based on distance from anchor region 202 (e.g., based on torque).

For example, the most stress is applied to a portion of region 210 that is closest to the anchor region 202 and the least stress (or no stress) is applied to the anchor region. The second most amount of stress is applied to a second region 212, an average amount of stress is applied to a middle region 214, a lower amount of stress is applied to a near tip region 216 region, and the even lower stress is applied a tip region 218.

In this case, an electrode (not shown) is positioned within the second region 212. The mechanical stress at this location produces a voltage based on the stress within the second region 212.

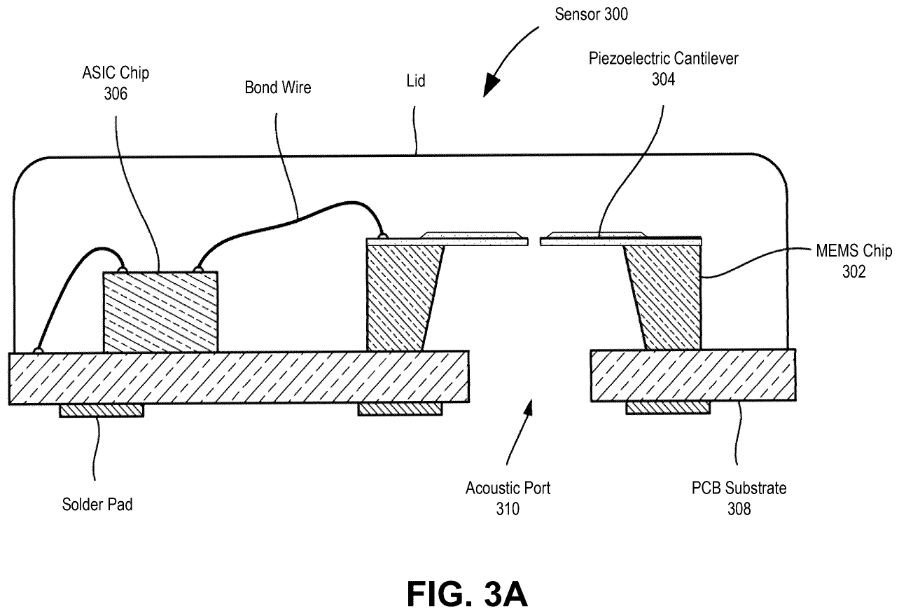

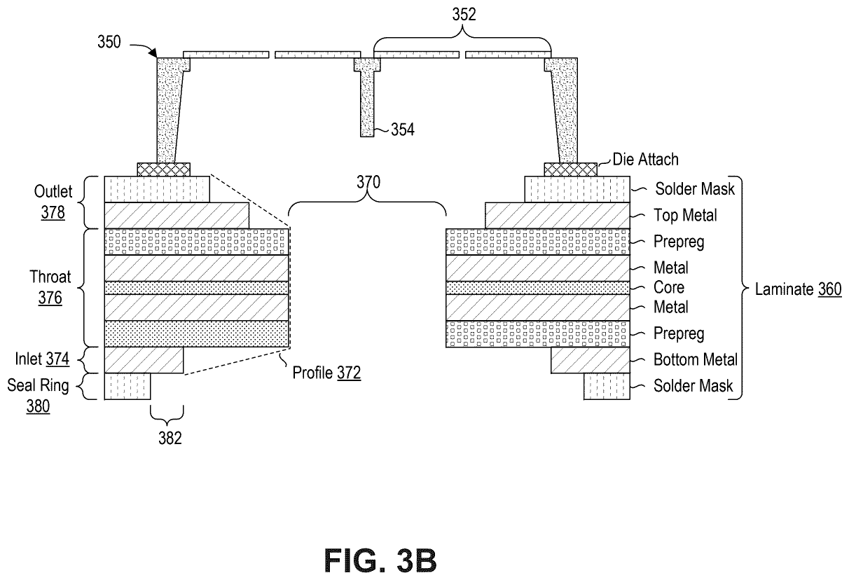

FIG. 3A illustrates aspects of a MEMS sensor 300 in accordance with aspects described herein. The MEMS sensor 300 includes a MEMS chip 302 having a transducer. The transducer may include a plurality of piezoelectric cantilevers 304 for generating electrical signals based on acoustic signal applied to the MEMS sensor. The piezoelectric cantilevers 304 may optionally include embossed structures to add rigidity, which in turn increases the output signal strength from the transducer. Additionally, the MEMS sensor 300 includes a lid, an application specific integrated circuit (ASIC) chip 306, and a printed circuit board (PCB) 308. As shown by FIG. 3A, transducers (e.g., the MEMS transducer 100 of FIG. 1) can be implemented on a MEMS chip 302 formed using a substrate (e.g., MEMS substrate 102 in FIG. 1). In some aspects, the MEMS chip 302 can include multiple transducers or other devices (not shown) in addition to the acoustic MEMS transducer. The sensor 300 includes an acoustic port 310 formed in the PCB 308, and the PCB 308 supports the MEMS chip 302 and the ASIC chip 306. The acoustic port 310 leads to a bottom aperture of the acoustic cavity (e.g., the acoustic cavity 108 of FIG. 1) in the MEMS substrate 102 of the MEMS chip 302. In other implementations, other such configurations of the acoustic port 310 can be used so long as a path for acoustic pressure to reach the electroacoustic structures (e.g., the piezoelectric cantilevers) is present.

The ASIC chip 306 and the MEMS chip 302 may be connected by an interconnect such as bond wires. In some aspects, rather than implement the system with two separate chips, some variants may implement both the MEMS chip 302 and the ASIC chip 306 as part of the same die. Accordingly, illustration of separate chips is for illustrative purposes only. In addition, in other embodiments the ASIC chip 306 may be implemented on a die in a separate package with one or more interconnects electrically coupling the MEMS chip 302 to the ASIC chip 306.

FIG. 3B illustrates a cross section of a MEMS sensor 300 in accordance with some aspects of the disclosure. In some aspects, the MEMS sensor 300 includes a transducer body 350 forming two MEMS transducers. The MEMS transducers each include a plurality of piezoelectric cantilevers 352 and are separated by a partition 354. The MEMS sensor 300 is formed on a laminate 360 (e.g., a package substrate) including a plurality of layers as shown in FIG. 3B. In some aspects, the plurality of layers is simplified for purposes of explanation to illustrate an order of forming the layers. In some cases, one or more of the layers may be interconnected. For example, the intermediate metal layers may be electrically connected to the bottom metal.

The MEMS sensor 300 includes a hole 370 (e.g., an aperture) formed in the laminate 360 for restricting airflow into the MEMS transducers. The hole 370 includes a profile 372 that includes an inlet 374, a throat 376 that restricts airflow, and an outlet to distribute the restricted airflow. The throat 376 is the smallest aperture and provides air resistance based on its dimensions. In some aspects, the outlet 378 is formed based on a design consideration due to process requirements of the solder mask, the top metal, and the prepreg layer, which is a dielectric material forming an insulation layer and may also be used as a planarization layer in some cases. For example, the solder mask and the top metal layer require a minimum tolerance to handle process variations, which results in forming the outlet 378.

Each of the layers forming the throat 376 are configured to restrict airflow based on a diameter of the hole 370. The laminate 360 also includes a seal ring 380 that is formed via the solder mask and an attachment material to bond the bottom metal to another surface. For example, region 382 may be electrically and mechanically attached to another surface (e.g., a PCB) via solder. In this case, the profile 372 does not extend into the seal ring 380. The seal ring 380 illustrated is a circular metal opening of the bottom metal layer and is connected to a low voltage potential (e.g., a ground) via soldered to a ground metal pad on a PCB. While example layers are shown for each of the outlet 378, throat 376, and inlet 374, it should be appreciated that these are examples only and different transducers may have different layer configurations based on the application or product.

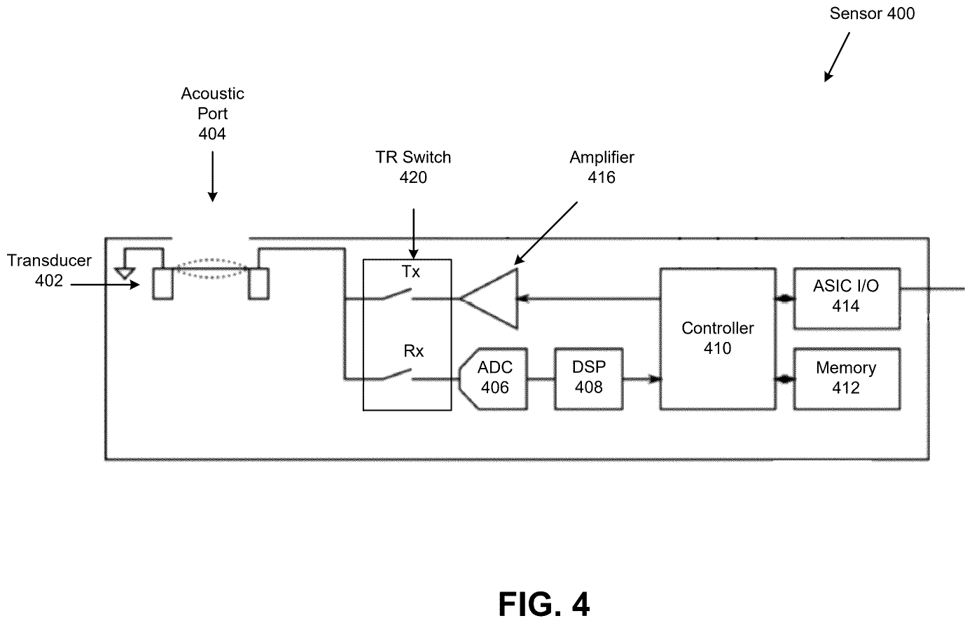

FIG. 4 illustrates aspects of a piezoelectric MEMS sensor 400 in accordance with aspects described herein. The sensor 400 includes a piezoelectric MEMS transducer 402 that interfaces with an acoustic port 404 for receiving acoustic signals. For example, the piezoelectric MEMS transducer 402 can be implemented on a MEMS chip (e.g., the MEMS chip 302 of FIGS. 3A and 3B). An output of the piezoelectric MEMS transducer 402 is coupled to an analog-to-digital converter (ADC) 406, which accepts an analog signal from the output of the transducer and converts the analog signal (e.g., which is a transduced signal from motion vibrations detected at the MEMS transducer 402) to a digital signal. An output of the ADC 406 is provided to a digital signal processor (DSP) 408, which can perform preprocessing, digital filtering, or other signal conditioning on the information from the transducer and provide an output signal to a controller 410. The controller 410 can further process the information from the transducer to generate a digital data signal corresponding to the analog signal output from the transducer 402. The digital data signal can be stored in a memory 412 on the sensor 400 or can be output to a data path via input/output (I/O) circuitry 414.

The acoustic port 404 is aligned with an acoustic port of the piezoelectric MEMS transducer 402 (e.g., the acoustic cavity 108 in FIG. 1). The piezoelectric MEMS sensor 400 allows acoustic signals to be received by the piezoelectric MEMS transducer 402 in a receive mode and generate electrical signals. In some cases, the sensor 400 can allow acoustic waves to be transmitted from the piezoelectric MEMS transducer 402 in an acoustic signal output mode. In this case, the piezoelectric MEMS sensor 400 may include switching circuit 420, and the controller 410 may control the piezoelectric MEMS sensor 400 to select between receive (e.g., acoustic signal input) and transmit (e.g., acoustic signal output) modes.

For example, in a transmit mode, an electrical signal (e.g., a pulse width modulation (PWM) signal, a digital signal, etc.) is received by the I/O circuitry 414 and provided to the controller 410. The electrical signal is modified by the controller 410 (e.g., filtering, and shaping for the transducer) and provided to an amplifier 416.

In a receive mode, the piezoelectric MEMS transducer 402 receives incident acoustic waves via the acoustic port 404 and converts the acoustic signals into electrical signals (e.g., a continuous wave voltage). The ADC 406 and the DSP 408 convert the analog electrical signal from the piezoelectric MEMS transducer 402 to a format acceptable to the controller 410, which can either store the signal in memory 412 or transmit the signal to additional processing circuitry of a larger device via the I/O circuitry 414. For example, the MEMS transducer 402 can be integrated into a wireless earbud, which may provide the acoustic signal to a wireless device (e.g., a phone, a laptop, etc.).

In some aspects, in a transmission mode, an electrical signal is provided from the I/O circuitry 414 to the controller 410. The electrical signal may be filtered by the controller 410 to shape the signal based on the piezoelectric MEMS transducer 402. The electrical signal may be converted into an analog electrical signal at the controller 410 and provided to the amplifier 416 to boost the power of the analog electrical signal. The amplifier 416, as part of transmission operations, can perform additional waveform conditioning and amplification (e.g., via a power amplifier). The piezoelectric MEMS transducer 402 receives the analog signal and generates an acoustic signal. In some cases, the amplifier 416 may be omitted, such as when the analog signal has sufficient power for acoustic transmission.

In some aspects, multiple separate sensor packages having MEMS acoustic transducers with overstress protection can be included in a single device. In other aspects, a shared package can be used for multiple transducers (e.g., on a shared PCB substrate such as the PCB 308 with the same lid).

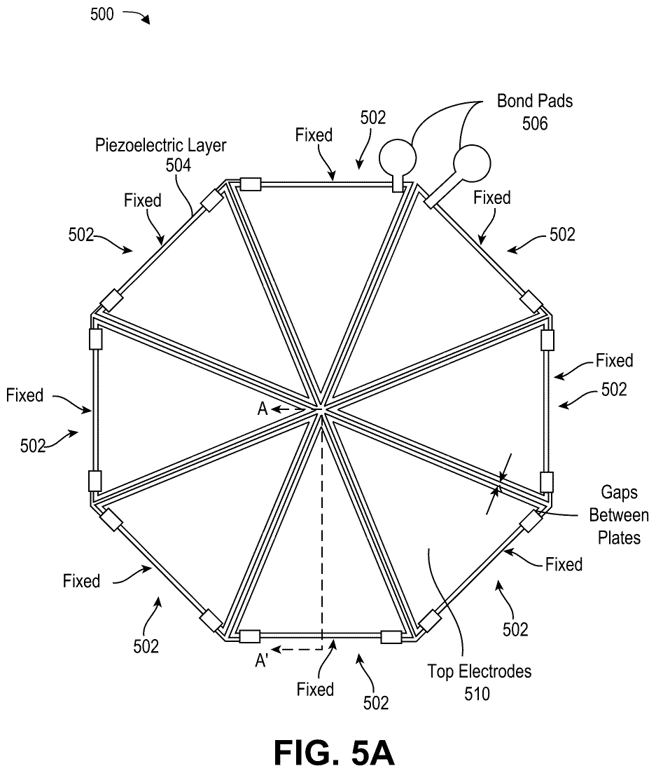

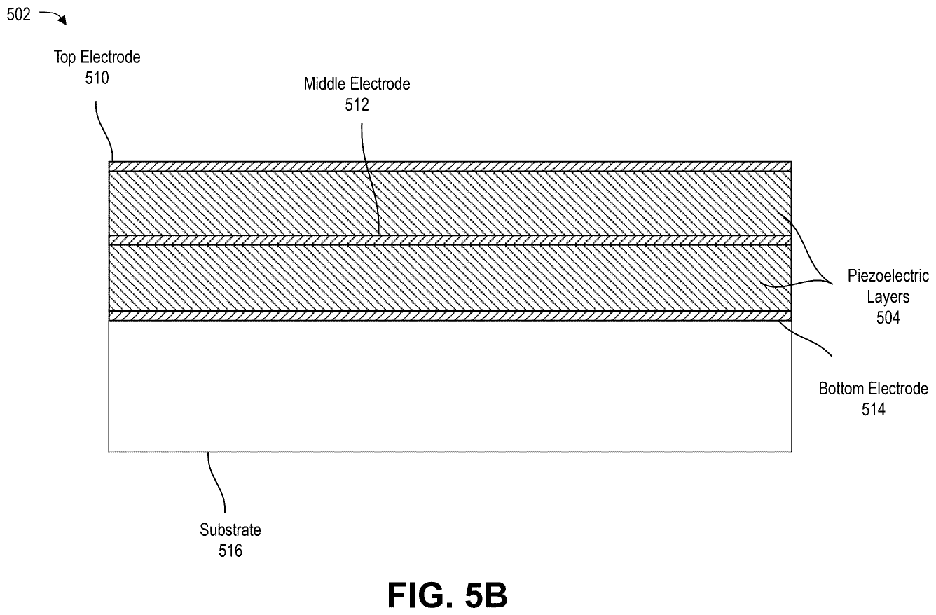

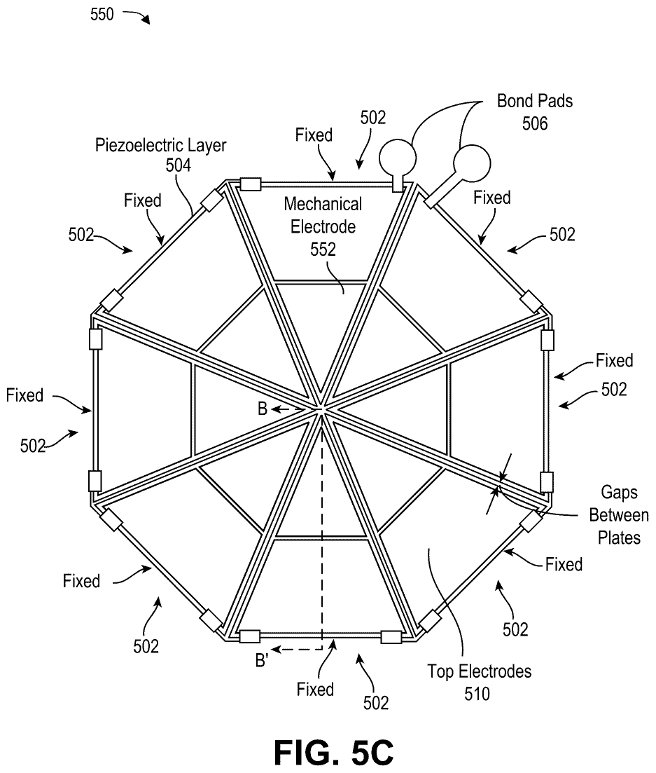

FIG. 5A illustrates a plan view of a MEMS piezoelectric transducer 500 in accordance with some aspects of the disclosure. The MEMS piezoelectric transducer 500 includes a plurality of piezoelectric cantilevers 502 that are configured to cover a cavity (e.g., the acoustic cavity 108 in FIG. 1). The piezoelectric cantilever 502 includes an associated length that is determined by the line segment from the tip of the central end that is perpendicular to the fixed extreme end of the fixed end. The line segment extends from the fixed end at the substrate to the tip of the central end. As described above, when sound vibrations are present at a surface of the deflection beams, the cantilevered beams will move due to the pressure (e.g., z direction movement in and out of the x-y plane illustrated in FIG. 5A. The movement in and out of this plane is referred to herein as vertical deflection. The deflection at the fixed end will be less than the deflection at the central end, with the amount of deflection increasing along the distance of the line segment away from the substrate toward the tip of the central end. The electrodes that generate the electrical signals at the bond pads 506 in response to the acoustic vibrations on the piezoelectric cantilevers 502 can add rigidity to the piezoelectric cantilever 502, and so in some implementations, placement of the top electrodes 510 can be limited to a space approximately two-thirds of the line segment distance from the fixed attachment to the substrate at the fixed end towards the tip of the central end (e.g., limited to a fixed end). In some implementations, an electrode layer can cover a surface or x-y plane cross-section of the entire illustrated fixed end of each of the cantilevered beams. In other implementations, smaller electrode shapes can be used in a portion of the fixed end of each of the piezoelectric cantilevers 502. In some aspects, the central end of each of the cantilevered beams does not include electrode layers. In some aspects, the electrode layers do not extend to the tip of the central end (e.g., the free movement end) of each piezoelectric cantilever 502 to avoid sensing free end movement in the deflection end (e.g., where the signal which is proportional to the stress in the cantilever is lower).

Other aspects of a piezoelectric MEMS acoustic transducer may use more or fewer piezoelectric cantilevers 502. Accordingly, as with other features, the discussion of eight piezoelectric cantilevers 502 is for illustrative purposes only. The piezoelectric cantilevers 502 are fixed at their respective bases and are configured to freely move around their fixed ends as part of acoustic layer operation in response to incoming/incident sound pressure (e.g., an acoustic wave). In some cases, piezoelectric cantilevers 502 configured as triangles provide a benefit over rectangular cantilevers and can be more simply configured to form a gap controlling geometry separating an acoustic port on one side of the cantilevers of the piezoelectric MEMS acoustic transducer from an air pocket on the other side of the cantilevers. Specifically, when the piezoelectric cantilevers 502 bend up or down due to either sound pressure or residual stress, the gaps between adjacent piezoelectric cantilevers 502 typically remain relatively small and uniform in the example symmetrical shapes with fixed ends using the piezoelectric cantilevers 502.

In some cases, the top electrodes 510 are electrically connected in series to achieve the desired capacitance and sensitivity values. In addition to the top electrodes 510, the rest of the piezoelectric cantilever 502 also may be covered by metal to maintain certain mechanical strength of the structure. For example, in some implementations, middle electrodes of the piezoelectric MEMS acoustic (e.g., middle electrodes 512 shown in FIG. 5B) may be covered in metal. In some cases, the middle electrodes (e.g., middle electrodes 512 of FIG. 5B) may not contribute to the electrical signal of the microphone output. In some aspects, a MEMS acoustic transducer can include piezoelectric cantilevers 502 without middle electrodes 512.

As described above, as a piezoelectric cantilever 502 bends or flexes around the fixed end as part of acoustic layer operation, the top electrodes 510 and/or the middle electrodes 512 generate an electrical signal. The electrical signal from an upward flex (e.g., as illustrated in FIG. 2) will be inverted compared with the signal of a downward flex. In some implementations, the signal from each piezoelectric cantilever 502 can be connected to the same signal path so that the electrical signals from each piezoelectric cantilever 502 are combined (e.g., shared bond pads 506). In other aspects, each piezoelectric cantilever 502 may have a separate signal path, allowing the signal from each piezoelectric cantilever 502 to be processed separately. In some aspects, groups of piezoelectric cantilevers 502 can be connected in different combinations. In some aspects, switching circuitry or groups of switches can be used to reconfigure the connections between multiple piezoelectric cantilevers 502 to provide different characteristics for different operating modes, such as transmit and receive modes.

In one aspect, adjacent piezoelectric cantilevers 502 can be connected to separate electrical paths, such that every other piezoelectric cantilever 502 has a shared path. The electrical connections in such a configuration can be flipped to create a differential signal. Such an aspect can operate such that when an acoustic signal incident on a piezoelectric MEMS acoustic transducer causes all the cantilevers 502 to flex upward, half of the cantilevers 502 create a positive signal, and half the cantilevers 502 create a negative signal. The two separate signals can then be connected to opposite inverting and non-inverting ends of an amplifier of an analog front end. Similarly, when the same acoustic vibration causes the cantilevers 502 to flex downward, the signals of the two groups will flip polarity, providing for a differential electrical signal from the piezoelectric MEMS acoustic transducer.

Alternatively, rather than alternating piezoelectric cantilevers 502 within a single piezoelectric MEMS transducer to create a differential signal, identical MEMS transducers can be placed across a shared acoustic port with the connections to the amplifier of an analog front-end reversed and coupled to different inverting and non-inverting inputs of a differential amplifier of the analog front-end to create the differential signal using multiple piezoelectric MEMS transducers.

FIG. 5B illustrates a cross-sectional view of a MEMS piezoelectric transducer in accordance with some aspects of the disclosure. In particular, FIG. 5B shows an example cross-sectional view of one of the cantilevers 502 along lines A-A′ during the semiconductor manufacturing process.

The piezoelectric cantilever 502 can be fabricated by one or multiple layers of piezoelectric material interleaved between top electrodes 510, middle electrodes 512, and bottom electrodes 514. The piezoelectric layers 504 can be made using piezoelectric materials used in MEMS devices, such as one or more of aluminum nitride (AlN), aluminum scandium nitride (AlScN), zinc oxide (ZnO), or lead zirconate titanate (PZT). In some examples, the edge electrodes (including top electrode 510 and bottom electrode 514) and/or the middle electrodes 512 can be made using metal materials used in MEMS devices, such as one or more of molybdenum (Mo), platinum (Pt), nickel (Ni), and aluminum (Al), and/or any combination thereof. In some cases, the top electrodes 510, middle electrodes 512, and bottom electrodes 514 can be formed from a non-metal, such as doped polysilicon. In some implementations, the top electrodes 510 may cover a portion of the piezoelectric cantilever 502, (e.g., from the fixed end to about one third of the piezoelectric cantilever 502), in such cases where these areas generate electrical energy more efficiently within the piezoelectric layer 504 than the areas near the central end (e.g., the free movement end) of each piezoelectric cantilever 502. Specifically, high-stress concentration in areas near the fixed end induced by the incoming sound pressure is converted into an electrical signal by direct piezoelectric effect.

In some aspects, the piezoelectric cantilevers 502 and corresponding layers (e.g., the top electrodes 510, middle electrodes 512, and bottom electrodes 514, and the piezoelectric layer 504) may be formed on a MEMS substrate 516 using various semiconductor processes. In some aspects, the piezoelectric cantilevers 502 are separated from the MEMS substrate 516 during the semiconductor manufacturing process.

FIG. 5C illustrates a plan view of a MEMS piezoelectric transducer 550 in accordance with some aspects of the disclosure. The MEMS piezoelectric transducer 550 includes a mechanical electrode 552 that is electrically isolated from the top electrode 510. For example, a region between the top electrodes 510 and the mechanical electrode 552 can be etched during manufacturing.

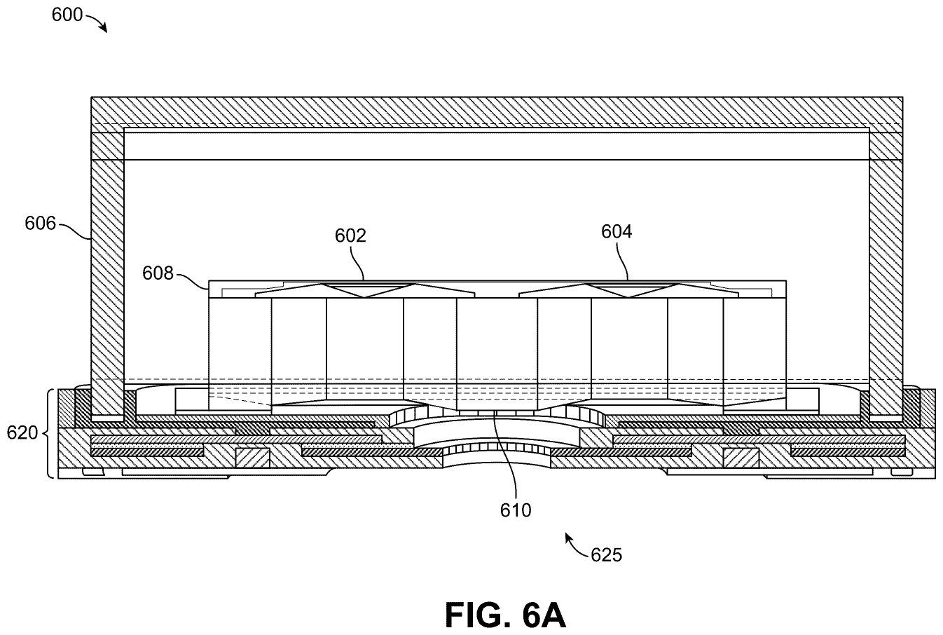

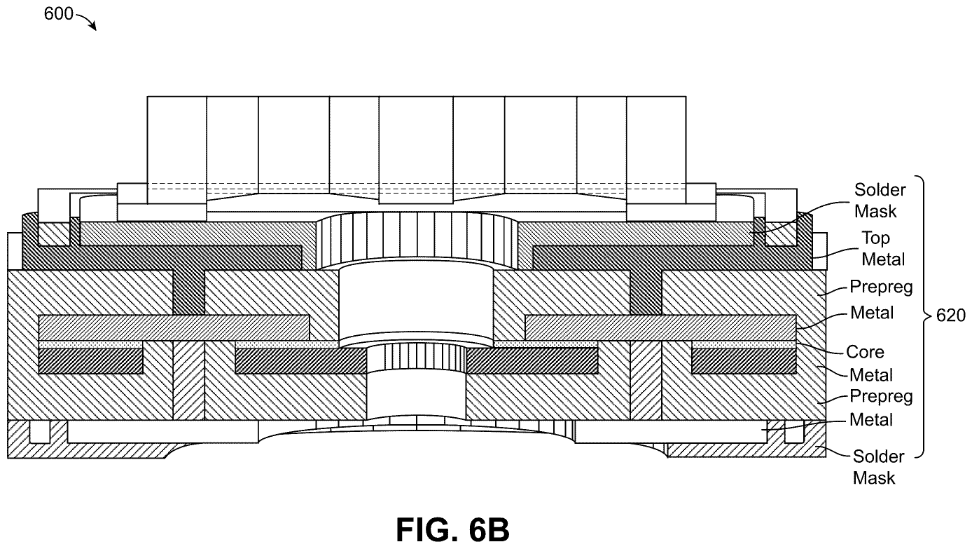

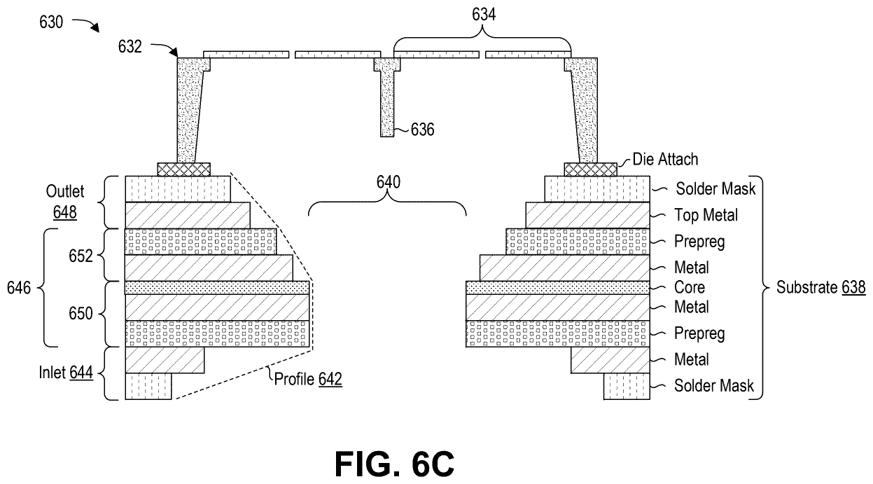

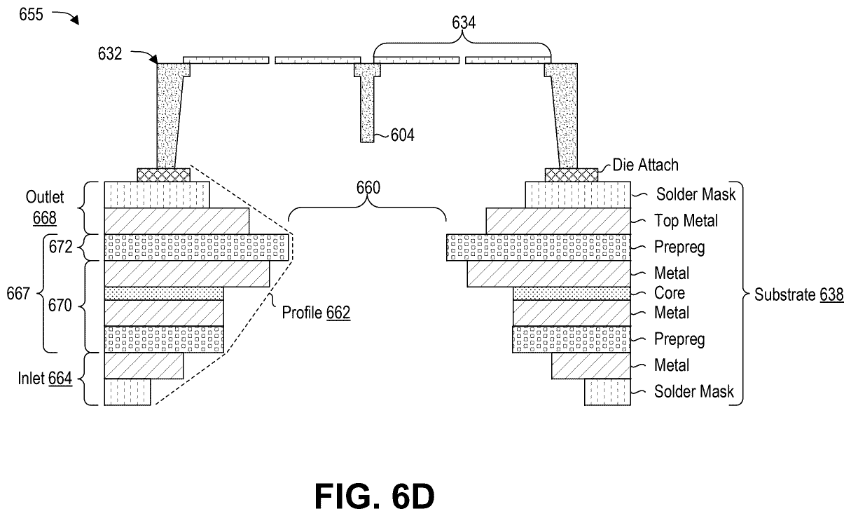

FIG. 6A is a perspective view of a packaged MEMS transducer 600 that includes a first MEMS transducer 602 and a second MEMS transducer 604 encapsulated by a protective cover 606 in accordance with some aspects of the disclosure. The MEMS transducers 602 and 604 are formed with a transducer body 608 and are separated by a partition 610. The transducer body 608 is fixed to a laminate (e.g., the laminae 360) formed by plurality of layers 620 (e.g., the laminate 360) and including a hole 625 (or aperture). In some aspects, the plurality of layers 620 includes a progressive profile that includes at least an additional converging section or diverging section. The converging section and diverging section are more clearly illustrated in other figures described herein.

FIG. 6B is an enlarged perspective view of a packaged MEMS transducer 600 in accordance with some aspects of the disclosure. For example, a MEMS transducer (e.g., the MEMS transducer 100) is mounted to a laminate (e.g., the laminate 360) and a protective cover 606 is placed over the MEMs transducer to form the packaged MEMS transducer 600. FIG. 6B illustrates the plurality of layers 620 of the MEMS transducer 600 and the interconnections of the different layers. FIG. 6B also illustrates that, according to some aspects, a portion of the plurality of layers include incrementally varying apertures (apertures with varying aperture sizes) relative to at least one adjacent layer. The incrementally varying apertures relative to at least one adjacent layer form an additional converging section or diverging section and reduce the thickness of the throat. In some aspects, reducing the thickness of the throat and adding at least one of the converging section or diverging section improves airflow (e.g., so that air is more restricted from coming into contact with and thus causing damage to one or more MEMS transducers) and reduces mass loading, which improves acoustic performance without increasing acoustic resistance. SNR can thus be improved and the resonance of the piezoelectric materials can be maintained.

FIG. 6C is a cross-sectional view of a MEMS sensor 630 in accordance with some aspects of the disclosure. The MEMS sensor 630 includes two MEMS transducers that are separated by a partition 636. For example, a MEMS transducer is shown that includes a transducer body 632 with piezoelectric cantilevers 634 disposed on a top surface of the transducer body 632. In some aspects, the MEMS sensor 630 may include a single MEMS transducer or more than two MEMS transducers (e.g., three MEMS transducers, four MEMS transducers, etc.). The transducer body 632 is mounted to a substrate 638 including a plurality of layers. As shown in FIG. 6C, the plurality of layers includes (from top to bottom) a first solder mask layer, a first (top) metal layer, a prepreg layer, a second metal layer, a first core layer, a third metal layer, a second prepreg layer, a fourth metal layer, and a second solder mask layer.

The MEMS sensor 630 includes a hole 640 that is formed by varying apertures (or holes) of the layers, including different sized apertures for some of the layers (e.g., the apertures increasingly become smaller in size from the first solder mask at the top of the substrate 638 to the second metal layer above the first core layer) and similarly or same sized apertures for other layers (e.g., the first core layer, the third metal layer, and the second core layer have similarly or same sized apertures). While a single hole 640 is shown in the example of FIG. 6C (and other examples described herein), in some cases, the MEMS sensor 630 (and other MEMS sensors described herein) may include multiple holes, such as if the MEMS sensor includes multiple MEMS transducers. The hole 640 can be formed (e.g., during fabrication of the MEMS sensor 630) based on performance and airflow considerations. For example, the hole 640 may have a progressive diverging tapered profile 642, which can reduce airflow resistance (e.g., gas impedance). The hole 640 includes an inlet 644, a middle region 646, and an outlet 648. The outlet 648 can be formed based on performance considerations (e.g., step and process tolerances).

The middle region 646 includes a throat 650 formed with core layers (including the first core layer and the second core layer, which may be a PCB core material) and the third metal layer of the substrate 638. The throat 650 is the smallest aperture associated with the hole 640 and presents the most resistance to air flow. The middle region 646 also includes a diverging section 652 that is formed for example with the prepreg layer and the second metal layer. The diverging section 652 interfaces with the throat 650 and incrementally increases aperture size in the direction of airflow (e.g., upward towards the piezoelectric cantilevers 634). In this case, the diverging section 652 is designed to increase size (thus improving acoustic characteristics of the MEMS sensor 630) and reduce airflow resistance by at least reducing a thickness of the throat 650. The diverging section 652 includes layers positioned after the throat 650 in the direction of airflow (e.g., toward the first MEMS transducer 602 or the second MEMS transducer 604). Each layer of the diverging section 652 includes an aperture that incrementally increases in the direction of airflow. The diverging section 652 also reduces the airflow resistance from the throat 650. In the example of FIG. 6C, the layers within the middle region 646 are intentionally formed in a step wise fashion (within differing apertures) to reduce air resistance without affecting mass loading.

FIG. 6D is a cross-sectional view of a MEMS sensor 655 in accordance with some aspects of the disclosure. The MEMS sensor 655 is configured similarly to the MEMS sensor 630 of FIG. 6C and differing features are described. In one aspect, the hole 660 is configured to have a different profile (profile 662) as compared to the profile 642 shown in FIG. 6C. The hole 660 includes an inlet 664, a middle region 667, and an outlet 668. The outlet 648 can be formed based on performance considerations (e.g., step and process tolerances).

The middle region 667 includes a converging section 670 (formed based on two core layers (e.g., a PCB core material) and two metal layers) and a throat 672 that restricts airflow. The converging section 670 includes layers positioned before the throat 672 in the direction of airflow (e.g., toward the first MEMS transducer 602 or the second MEMS transducer 604). Each layer of the converging section 670 includes an aperture that decreases in size in the direction of airflow. For example, the layers of the converging section 670 include apertures that decrease in radius. The throat 672 interfaces with the outlet 668. In this case, the converging section 670 is designed to reduce airflow resistance into and out of the throat 672 at least by increasing a size of the apertures of the various layers of the middle region 667. In this aspect, the layers within the middle region 667 are intentionally formed in a step wise fashion to reduce air resistance without affecting mass loading.

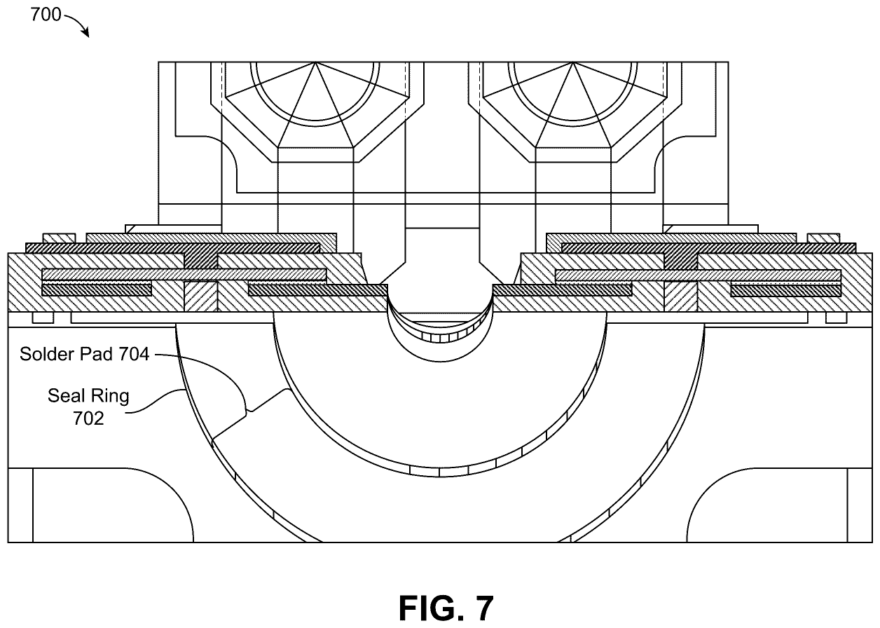

FIG. 7 is a perspective view of a cross-section of a packaged MEMS transducer 700 and illustrates a bottom surface of the laminate (e.g., the laminate 360) having a plurality of layers in accordance with some aspects of the disclosure. FIG. 7 illustrates a seal ring 702 that will be formed based on mechanically attaching the MEMS transducer 700 via the solder pad 704 (e.g., the bottom metal in FIG. 3B, FIG. 6B, FIG. 6C, and FIG. 6D).

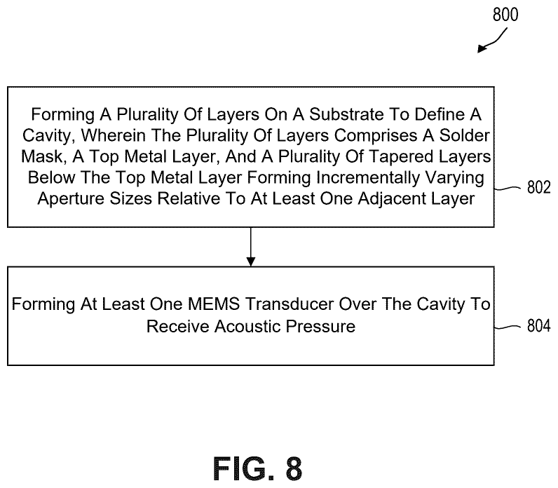

FIG. 8 illustrates a method 800 (or process) for forming a MEMS transducer including a piezoelectric cantilever in accordance with some aspects of the disclosure.

At block 802, the method includes forming a plurality of layers on a substrate to define a cavity. The plurality of layers comprises a solder mask, a top metal layer, and a plurality of tapered layers below the top metal layer. The plurality of tapered layers include incrementally varying aperture sizes relative to at least one adjacent layer. For example, the plurality of tapered layers may form a converging section that includes incrementally decreasing aperture sizes. The converging section is adjacent to and precedes the throat in the direction of air flow. The throat at least one layer having the smallest aperture relative to the plurality of layers. In another example, the plurality of tapered layers may form a diverging section that includes incrementally decreasing aperture sizes. The diverging section is adjacent to and succeeds the throat in the direction of air flow.

At block 804, the method includes forming at least one MEMS transducer over the cavity to receive acoustic pressure. For example, the MEMS transducer includes piezoelectric cantilevers that are configured to generate an electrical signal corresponding to air flow through the cavity.

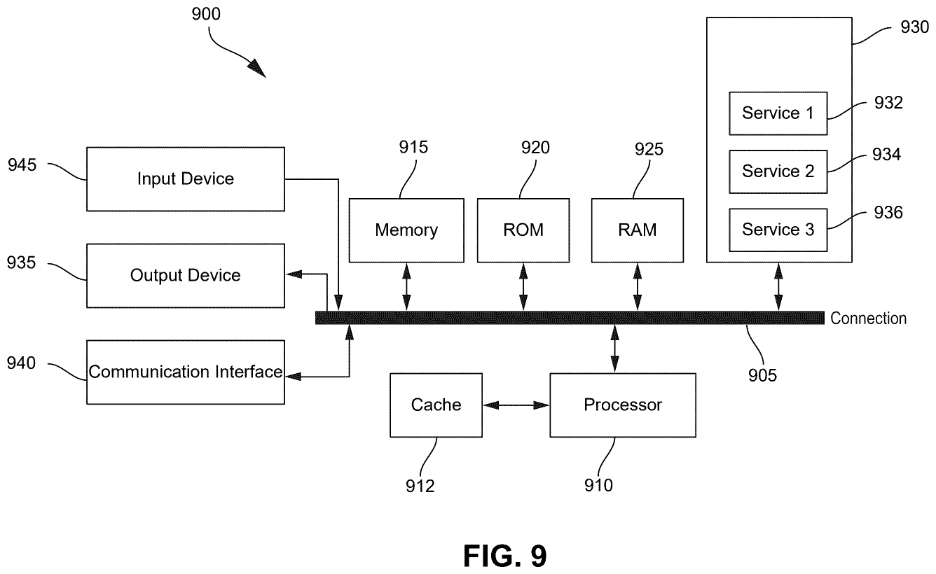

FIG. 9 is a diagram illustrating an example of a system for implementing certain aspects of the present technology. In particular, FIG. 9 illustrates an example of computing system 900 which can include MEMS transducers or devices including MEMS devices having piezoelectric cantilevers in accordance with aspects described herein. An acoustic transducer can be integrated, for example, with any computing device making up internal computing system, a remote computing system, a camera, or any component thereof in which the components of the system are in communication with each other using connection 905. Connection 905 may be a physical connection using a bus, or a direct connection into processor 910, such as in a chipset architecture. Connection 905 may also be a virtual connection, networked connection, or logical connection.

Example computing system 900 includes at least one processing unit (CPU or processor) 910 and connection 905 that communicatively couples various system components including system memory 915, such as read-only memory (ROM) 920 and random access memory (RAM) 925 to processor 910. Computing system 900 may include a cache 912 of high-speed memory connected directly with, in close proximity to, or integrated as part of processor 910.

Processor 910 may include any general purpose processor and a hardware service or software service, such as services 932, 934, and 936 stored in storage device 930, configured to control processor 910 as well as a special-purpose processor where software instructions are incorporated into the actual processor design. Processor 910 may essentially be a completely self-contained computing system, containing multiple cores or processors, a bus, memory controller, cache, etc. A multi-core processor may be symmetric or asymmetric.

To enable user interaction, computing system 900 includes an input device 945, which may represent any number of input mechanisms, such as a microphone for speech or audio detection (e.g., piezoelectric MEMS transducer or a MEMS transducer system in accordance with aspects described above, etc.) along with other input devices 945 such as a touch-sensitive screen for gesture or graphical input, keyboard, mouse, motion input, speech, etc. Computing system 900 may also include output device 935, which may be one or more of a number of output mechanisms. In some instances, multimodal systems may enable a user to provide multiple types of input/output to communicate with computing system 900.

Computing system 900 may include communications interface 940, which may generally govern and manage the user input and system output. The communication interface may perform or facilitate receipt and/or transmission wired or wireless communications using wired and/or wireless transducers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 940 may also include one or more Global Navigation Satellite System (GNSS) receivers or transducers that are used to determine a location of the computing system 900 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 930 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1 (L1 ) cache, Level 2 (L2 ) cache, Level 3 (L3 ) cache, Level 4 (L4 ) cache, Level 5 (L5 ) cache, or other (L #) cache), resistive random-access memory (RRAM/ReRAM), phase change memory (PCM), spin transfer torque RAM (STT-RAM), another memory chip or cartridge, and/or a combination thereof.

The storage device 930 may include software services, servers, services, etc., that when the code that defines such software is executed by the processor 910, it causes the system to perform a function. In some embodiments, a hardware service that performs a particular function may include the software component stored in a computer-readable medium in connection with the necessary hardware components, such as processor 910, connection 905, output device 935, etc., to carry out the function. The term “computer-readable medium” includes, but is not limited to, portable or non-portable storage devices, optical storage devices, and various other mediums capable of storing, containing, or carrying instructions(s) and/or data. A computer-readable medium may include a non-transitory medium in which data may be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the embodiments and examples provided herein, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments may be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

For clarity of explanation, in some instances the present technology may be presented as including individual functional blocks including devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual embodiments may be described above as a process or method which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Processes and methods according to the above-described examples may be implemented using computer-executable instructions that are stored or otherwise available from computer-readable media. Such instructions may include, for example, instructions and data which cause or otherwise configure a general purpose computer, special purpose computer, or a processing device to perform a certain function or group of functions. Portions of computer resources used may be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some embodiments the computer-readable storage devices, mediums, and memories may include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and may take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also may be embodied in peripherals or add-in cards. Such functionality may also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purpose computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium including program code including instructions that, when executed, performs one or more of the methods, algorithms, and/or operations described above. The computer-readable data storage medium may form part of a computer program product, which may include packaging materials. The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that may be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Where components are described as being “configured to” perform certain operations, such configuration may be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

A number of implementations have been described. Nevertheless, it will be understood that various modifications may be made without departing from the spirit and scope of the disclosure. Other embodiments are within the scope of the claims.

Illustrative aspects of the disclosure include:

Aspect 1. A MEMS transducer, comprising: a transducer body including an acoustic cavity extending from a bottom surface to a top surface; and a substrate including a plurality of layers and coupled to the bottom surface of the transducer body, the substrate including a hole formed by the plurality of layers, wherein the plurality of layers comprises a solder mask, a top metal layer, and a plurality of tapered layers below the top metal layer forming incrementally varying aperture sizes relative to at least one adjacent layer.

Aspect 2. The MEMS transducer of Aspect 1, wherein the hole comprises a converging inlet, a diverging outlet, and a middle region between the converging inlet and the diverging outlet including a converging region or a diverging region.

Aspect 3. The MEMS transducer of Aspect 2, wherein the diverging outlet is formed based on a step associated with at least the solder mask, the top metal layer, and a dielectric layer.

Aspect 4. The MEMS transducer of Aspect 3. wherein the solder mask is formed on the top metal layer, and the top metal layer is formed on the dielectric layer.

Aspect 5. The MEMS transducer of any of Aspects 2 to 4, wherein an angle of the diverging region with respect to a direction of air flow is less than an angle of the diverging outlet, and wherein the diverging region interfaces with the diverging outlet.

Aspect 6. The MEMS transducer of Aspect 5, wherein the diverging region comprises at least a dielectric layer and an intermediate metal layer having different steps.

Aspect 7. The MEMS transducer of any of Aspects 2 to 6, wherein the middle region includes a throat configured to impede airflow.

Aspect 8. The MEMS transducer of Aspect 7, wherein the throat has a smallest aperture size relative to each layer in the plurality of layers.

Aspect 9. The MEMS transducer of any of Aspects 7 to 8, wherein the throat comprises an intermediate metal layer and a dielectric layer.

Aspect 10. The MEMS transducer of any of Aspects 2 to 9, wherein an angle of the converging region with respect to a direction of air flow is less than an angle of the converging inlet, and wherein the converging region interfaces with the converging inlet.

Aspect 11. The MEMS transducer of Aspect 10, wherein the converging region comprises at least one layer of substrate core and a bottom metal layer.

Aspect 12. The MEMS transducer of Aspect 11, wherein the bottom metal layer is configured to form a seal ring and electrically connect the MEMS transducer to a low voltage source.

Aspect 13. The MEMS transducer of any of Aspects 2 to 12, wherein the converging inlet receives acoustic signals, a throat of the middle region that interfaces with the converging inlet and impedes the acoustic signals, the diverging region interfacing with the throat and dispersing acoustic signal, and the diverging outlet interfacing with the diverging region and providing the acoustic signals to the acoustic cavity.

Aspect 14. The MEMS transducer of any of Aspects 2 to 13, wherein the converging inlet receives acoustic signals, the converging region interfacing with the converging inlet and providing the acoustic signals to a throat, the throat interfaces with the converging inlet and impedes the acoustic signals, and the diverging outlet interfacing with the throat and providing the acoustic signals to the acoustic cavity.

Aspect 15. The MEMS transducer of any of Aspects 1 to 14, further comprising a piezoelectric cantilever disposed over the top surface.

Aspect 16. An apparatus, comprising: a MEMS transducer for generating an electrical signal based on acoustic signals, wherein the MEMS transducer includes: a transducer body including an acoustic cavity extending from a bottom surface to a top surface; and a substrate including a plurality of layers and coupled to the bottom surface of the transducer body, the substrate including a hole formed by the plurality of layers, and wherein the plurality of layers comprises a solder mask, a top metal layer, and a plurality of tapered layers below the top metal layer having incrementally varying aperture sizes relative to at least one adjacent layer.

Aspect 17. The apparatus of Aspect 16, wherein the hole comprises a converging inlet, a diverging outlet, and a middle region between the converging inlet and the diverging outlet including a converging region or a diverging region.

Aspect 18. The apparatus of Aspect 17, wherein the converging inlet is formed based on a step associated with at least the solder mask, the top metal layer, and a dielectric layer.

Aspect 19. The apparatus of Aspect 18, wherein the solder mask is formed on the top metal layer, and the top metal layer is formed on the dielectric layer.

Aspect 20. The apparatus of any of Aspects 17 to 19, wherein an angle of the diverging region with respect to a direction of air flow is less than an angle of the diverging outlet, and wherein the diverging region interfaces with the diverging outlet.

Aspect 21. The apparatus of Aspect 20, wherein the diverging region comprises at least a dielectric layer and an intermediate metal layer having different steps.

Aspect 22. The apparatus of any of Aspects 17 to 21, wherein the middle region includes a throat configured to impede airflow.

Aspect 23. The apparatus of Aspect 22, wherein the throat has a smallest area.

Aspect 24. The apparatus of any of Aspects 22 to 23, wherein the throat comprises an intermediate metal layer and a dielectric layer.

Aspect 25. The apparatus of any of Aspects 17 to 24, wherein an angle of the converging region with respect to a direction of air flow is less than an angle of the converging inlet, and wherein the converging inlet is adjacent to the converging region in the direction of air flow.

Aspect 26. The apparatus of Aspect 25, wherein the converging region comprises at least one layer of substrate core and a bottom metal layer.

Aspect 27. The apparatus of Aspect 26, wherein the bottom metal layer is configured to form a seal ring and electrically connect the MEMS transducer to a low voltage source.

Aspect 28. The apparatus of any of Aspects 17 to 27, wherein the converging inlet receives acoustic signals, a throat of the middle region that interfaces with the converging inlet and impedes the acoustic signals, the diverging region interfacing with the throat and dispersing acoustic signal, and the diverging outlet interfacing with the diverging region and providing the acoustic signals to the acoustic cavity.

Aspect 29. The apparatus of any of Aspects 17 to 28, wherein the converging inlet receives acoustic signals, the converging region interfacing with the converging inlet and providing the acoustic signals to a throat, the throat interfaces with the converging inlet and impedes the acoustic signals, and the diverging outlet interfacing with the throat and providing the acoustic signals to the acoustic cavity.

Aspect 30. The apparatus of any of Aspects 16 to 29, further comprising a piezoelectric cantilever disposed over the top surface.

Aspect 31. A method of fabricating a MEMS transducer, comprising: forming a plurality of layers on a substrate to define a cavity, wherein the plurality of layers comprises a solder mask, a top metal layer, and a plurality of tapered layers below the top metal layer forming incrementally varying aperture sizes relative to at least one adjacent layer; and forming at least one MEMS transducer over the cavity to receive acoustic pressure.

Aspect 32. An apparatus, comprising: a MEMS transducer having an acoustic cavity and configured to generate an electrical signal based on acoustic signals; and a multilayer substrate on which the transducer is disposed, the multilayer substrate having a shape that forms an aperture extending from a bottom of the multilayer substrate to a top of the multilayer substrate and forming a path to the acoustic cavity, the multilayer substrate comprising: one or more first layers; a plurality of second layers; and one or more third layers, the plurality of second layers disposed between the one or more first layers and the one or more third layers, each of the plurality of second layers extending into the aperture further than the layers of each of the one or more first layers and the one or more third layers, the plurality of second layers comprising at least a first layer and a second layer, the first layer extending into the aperture further than the second layer.

Aspect 33. The apparatus of Aspect 32, wherein each of the one or more first layers extends further into the aperture than each of the one or more third layers.

Aspect 34. The apparatus of any of Aspects 32 to 33, wherein the transducer comprises a piezoelectric cantilever extending over the acoustic cavity and disposed on a transducer body that is formed to define the acoustic cavity.

Aspect 35. The apparatus of any of Aspects 32 to 34, wherein the one or more first layers comprises at least a solder mask layer and a top metal layer.

Aspect 36. The apparatus of any of Aspects 32 to 35, wherein the plurality of second layers comprises at least a dielectric layer and a metal layer.

Aspect 37. The apparatus of any of Aspects 32 to 36, wherein the one or more first layers are positioned between the transducer and the plurality of second layers.

Aspect 38. The apparatus of Aspect 37, wherein a profile defined by the multilayer substrate along the aperture includes a converging inlet formed at least in part by the one or more third layers, a diverging outlet formed at least in part by the one or more first layers, and a middle region between the converging inlet and the diverging outlet formed by the plurality of second layers and including a converging region or a diverging region.

Aspect 39. The apparatus of Aspect 38, wherein an angle of the diverging region with respect to a direction of air flow is less than an angle of the diverging outlet, and wherein the diverging region interfaces with the diverging outlet.

What is claimed is:

1. A microelectromechanical system (MEMS) transducer, comprising:
a transducer body including an acoustic cavity extending from a bottom surface to a top surface;
a substrate including a plurality of layers and coupled to the bottom surface of the transducer body, the substrate including a hole formed by the plurality of layers, wherein the plurality of layers comprises a solder mask, a top metal layer, and a plurality of tapered layers below the top metal layer forming incrementally varying aperture sizes relative to at least one adjacent layer; and
a piezoelectric cantilever disposed over the top surface.

2. The MEMS transducer of claim 1, wherein the hole comprises a converging inlet, a diverging outlet, and a middle region between the converging inlet and the diverging outlet including a converging region or a diverging region.

3. The MEMS transducer of claim 2, wherein an angle of the diverging region with respect to a direction of air flow is less than an angle of the diverging outlet, and wherein the diverging region interfaces with the diverging outlet.

4. The MEMS transducer of claim 3, wherein the diverging region comprises at least a dielectric layer and an intermediate metal layer having different steps.

5. The MEMS transducer of claim 2, wherein the middle region includes a throat configured to impede airflow, and wherein the throat has a smallest aperture size relative to each layer in the plurality of layers.

6. The MEMS transducer of claim 5, wherein the throat comprises an intermediate metal layer and a dielectric layer.

7. The MEMS transducer of claim 2, wherein an angle of the converging region with respect to a direction of air flow is less than an angle of the converging inlet, and wherein the converging region interfaces with the converging inlet.

8. The MEMS transducer of claim 7, wherein the converging region comprises at least one layer of substrate core and a bottom metal layer, and
the bottom metal layer is configured to form a seal ring and electrically connect the MEMS transducer to a low voltage source.

9. The MEMS transducer of claim 2, wherein the converging inlet receives acoustic signals, a throat of the middle region that interfaces with the converging inlet and impedes the acoustic signals, the diverging region interfacing with the throat and dispersing acoustic signal, and the diverging outlet interfacing with the diverging region and providing the acoustic signals to the acoustic cavity.

10. The MEMS transducer of claim 2, wherein the converging inlet receives acoustic signals, the converging region interfacing with the converging inlet and providing the acoustic signals to a throat, the throat interfaces with the converging inlet and impedes the acoustic signals, and the diverging outlet interfacing with the throat and providing the acoustic signals to the acoustic cavity.

11. An apparatus, comprising:
a microelectromechanical system (MEMS) transducer having an acoustic cavity and configured to generate an electrical signal based on acoustic signals; and
a multilayer substrate on which the MEMS transducer is disposed, the multilayer substrate having a shape that forms an aperture extending from a bottom of the multilayer substrate to a top of the multilayer substrate and forming a path to the acoustic cavity, the multilayer substrate comprising:
one or more first layers;
a plurality of second layers; and
one or more third layers, the plurality of second layers disposed between the one or more first layers and the one or more third layers, each of the plurality of second layers extending into the aperture further than the layers of each of the one or more first layers and the one or more third layers, the plurality of second layers comprising at least a first layer and a second layer, the first layer extending into the aperture further than the second layer.

12. The apparatus of claim 11, wherein each of the one or more first layers extends further into the aperture than each of the one or more third layers.

13. The apparatus of claim 11, wherein the MEMS transducer comprises a piezoelectric cantilever extending over the acoustic cavity and disposed on a transducer body that is formed to define the acoustic cavity.

14. The apparatus of claim 11, wherein the one or more first layers comprises at least a solder mask layer and a top metal layer.

15. The apparatus of claim 11, wherein the plurality of second layers comprises at least a dielectric layer and a metal layer.

16. The apparatus of claim 11, wherein the one or more first layers are positioned between the MEMS transducer and the plurality of second layers.

17. The apparatus of claim 16, wherein a profile defined by the multilayer substrate along the aperture includes a converging inlet formed at least in part by the one or more third layers, a diverging outlet formed at least in part by the one or more first layers, and a middle region between the converging inlet and the diverging outlet formed by the plurality of second layers and including a converging region or a diverging region.

18. The apparatus of claim 17, wherein an angle of the diverging region with respect to a direction of air flow is less than an angle of the diverging outlet, and wherein the diverging region interfaces with the diverging outlet.

19. A method of fabricating a microelectromechanical system (MEMS) transducer, comprising:
forming a plurality of layers on a substrate to define a cavity, wherein the plurality of layers comprises a solder mask, a top metal layer, and a plurality of tapered layers below the top metal layer forming incrementally varying aperture sizes relative to at least one adjacent layer; and
forming at least one MEMS transducer over the cavity to receive acoustic pressure.
